(19) United States
(12) Patent Application Publication
(10) Pub. No.: US 2011/0124181 A1
(43) Pub. Date: May 26, 2011

(54) WORKPIECE CUTTING METHOD

(75) Inventors: Tamaki Suzuki, Ota-Ku (JP); Tatsuhiko Mori, Ota-ku (JP)

(73) Assignee: DISCO CORPORATION, Tokyo (JP)

(21) Appl. No.: 12/948,268

(22) Filed: Nov. 17, 2010

(30) Foreign Application Priority Data
Nov. 20, 2009 (JP) 2009-264749

(51) Int. Cl. H01L 21/78

(52) U.S. Cl. 438/464; 257/E21.599

(57) ABSTRACT

A cutting method for cutting a workpiece by using a cutting blade. The cutting method includes the steps of attaching an adhesive sheet to one surface of the workpiece, holding the workpiece through the adhesive sheet on holding means, and feeding the cutting blade into the workpiece until reaching the adhesive sheet as supplying a cutting fluid having a temperature of 10° C. or less, thereby cutting the workpiece.

### BACKGROUND OF THE INVENTION

1. Field of the Invention

The present invention relates to a workpiece cutting method for cutting a workpiece such as a semiconductor wafer by using a cutting blade.

2. Description of the Related Art

A workpiece such as a semiconductor wafer and any substrate of various materials is divided into individual chips by a dicing apparatus, and these chips are widely used in various electric equipment. A plurality of devices such as ICs and LSIs are formed on the front side of the semiconductor wafer. The substrates of various materials such as ceramic, resin, glass, and sapphire are used in electronic parts. To facilitate the handling of the individual chips divided from the workpiece and completely cut the workpiece, the workpiece is attached to a dicing tape as an adhesive sheet in dividing the workpiece. That is, the workpiece is supported through the dicing tape to an annular frame.

The dicing apparatus includes a chuck table (holding means) for holding the workpiece attached to the adhesive sheet, cutting means including a cutting blade for cutting the workpiece held on the chuck table, and a nozzle for supplying a cutting fluid to the cutting blade, wherein the cutting blade is rotated and fed into the workpiece until reaching the adhesive sheet, thereby dividing the workpiece (see Japanese Patent Laid-open No. 2000-349046, for example). In general, the adhesive sheet is composed of a base sheet and an adhesive layer formed on the base sheet. The base sheet is formed of polyvinyl chloride, polyolefin, or PET (polyethylene terephthalate), for example. The adhesive layer is formed of acrylic material or rubber material, for example. The workpiece is attached to the adhesive layer of the adhesive sheet (see Japanese Patent Laid-open No. Hei 5-156214, for example).

### SUMMARY OF THE INVENTION

In a conventional cutting method for cutting a workpiece such as a semiconductor wafer by using such a dicing apparatus, the dicing apparatus is set in a clean room, and a cutting water adjusted to a constant temperature range of 21° C. to 22° C. is supplied to the cutting blade during cutting of the workpiece. However, the adhesive layer supporting the workpiece is soft in this temperature range, causing a problem such that the chips on the adhesive layer may move in cutting the workpiece attached to the adhesive sheet by using the cutting blade. Particularly in the case of dividing the workpiece into individual small-sized chips each having a size of 10 mm or less, the movement of the chips becomes remarkable during cutting of the workpiece. The movement of the chips causes the generation of a defect called an odd form such that the side surface of each chip is not perpendicular to the adhesive sheet or other defects such as chipping and cracks on the front or back side of each chip.

It is therefore an object of the present invention to provide a workpiece cutting method which can prevent the generation of such defects.

In accordance with an aspect of the present invention, there is provided a cutting method for cutting a workpiece by using a cutting blade, said cutting method comprising the steps of attaching an adhesive sheet to one surface of said workpiece; holding said workpiece through said adhesive sheet on holding means; and feeding said cutting blade into said workpiece until reaching said adhesive sheet as supplying a cutting fluid having a temperature of 10° C. or less to said cutting blade, thereby cutting said workpiece.

According to the present invention, the cutting fluid cooled to 10° C. or less is supplied to the cutting blade during cutting of the workpiece. Accordingly, the adhesive layer of the adhesive sheet is cooled to be hardened by the cutting fluid led to the outer edge of the cutting blade as a cutting point or by the cutting fluid scattered on the workpiece. As a result, each chip is prevented from moving during cutting of the workpiece, so that the defects can be suppressed.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view of a cutting apparatus used in performing a cutting method according to a preferred embodiment of the present invention;

FIG. 2 is a perspective view of a semiconductor wafer supported through an adhesive sheet (dicing tape) to an annular frame;

FIG. 3 is a perspective view of a cutting blade surrounded by a wheel cover;

FIG. 4 is a side view showing the cutting blade and the wheel cover shown in FIG. 3;

FIG. 5 is a sectional view of the semiconductor wafer cut by the cutting method of the present invention; and

FIG. 6 is a sectional view of a semiconductor wafer cut by a conventional method, showing the generation of an odd form on each chip.

### DETAILED DESCRIPTION OF THE PREFERRED EMBODIMENTS

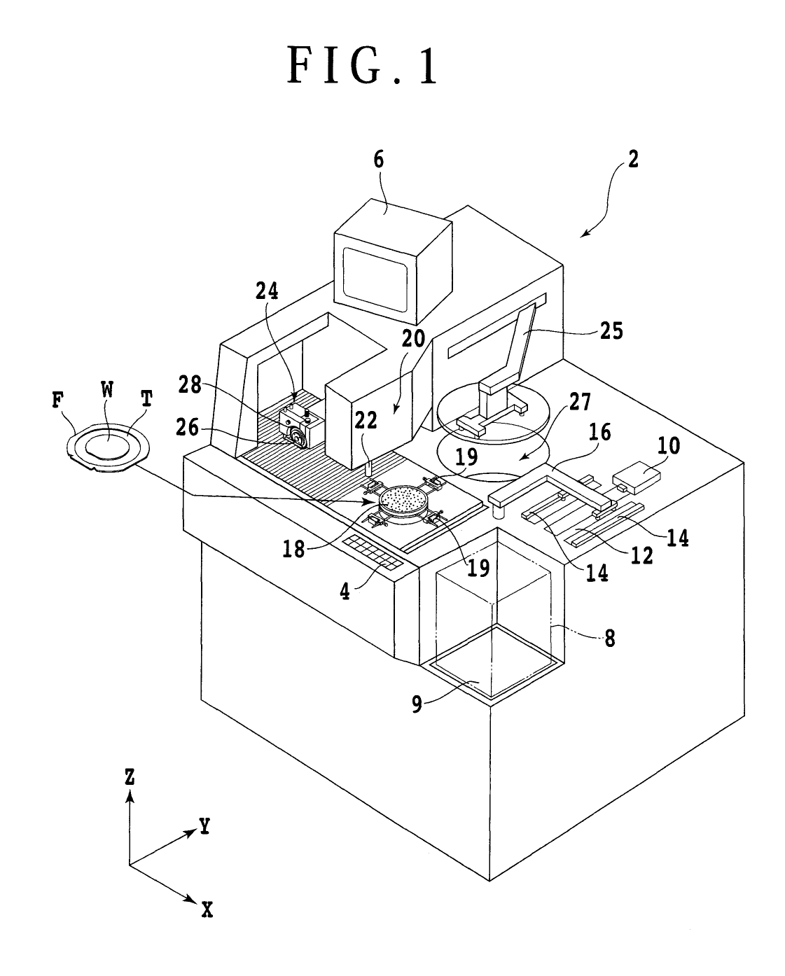

A preferred embodiment of the present invention will now be described in detail with reference to the drawings. FIG. 1 is a perspective view of a cutting apparatus (dicing apparatus) 2 used in performing a cutting method according to a preferred embodiment of the present invention. Operation means 4 for allowing an operator to input instructions such as processing conditions to the cutting apparatus 2 is provided at the front portion of the cutting apparatus 2. Display means 6 such as a CRT for displaying a guide view to the operator or an image obtained by imaging means to be hereinafter described is provided on the upper part of the apparatus.

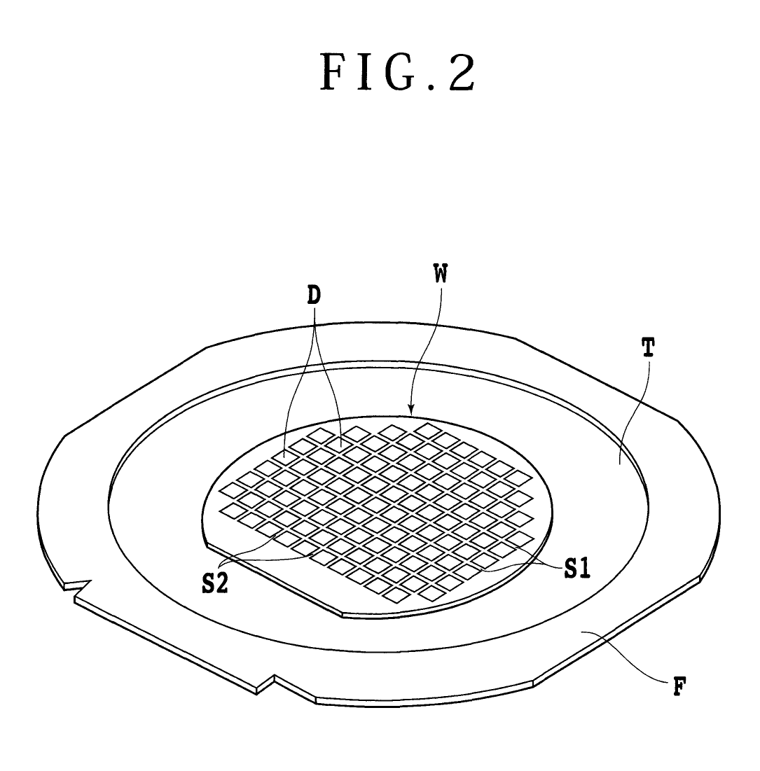

As shown in FIG. 2, a plurality of first streets S1 and a plurality of second streets S2 perpendicular to the first streets S1 are formed on the front side of a semiconductor wafer W as a workpiece to be processed. A plurality of devices D are formed on the front side of the wafer W so as to be partitioned by the first and second streets S1 and S2. The back side of the wafer W is attached to a dicing tape T as an adhesive sheet at a central portion thereof, and the peripheral portion of the dicing tape T is attached to an annular frame F. Accordingly, the wafer W is supported through the dicing tape T to the annular frame F. Referring back to FIG. 1, a plurality of (e.g., 25) wafers W each supported through the dicing tape T to the annular frame F are stored in a wafer cassette 8. The wafer cassette 8 is placed on a vertically movable cassette elevator 9.

Provided on the rear side of the wafer cassette 8 is ejecting/inserting means 10 for ejecting the wafer W from the wafer cassette 8 before cutting and inserting the wafer W into the wafer cassette 8 after cutting. A temporary setting area 12 for temporarily setting the wafer W before cutting or after cutting is provided between the wafer cassette 8 and the ejecting/inserting means 10. Further, positioning means 14 for positioning the wafer W is provided in the temporary setting area 12. First carrying means 16 having a pivotable arm for carrying the wafer W by holding the annular frame F under suction is provided in the vicinity of the temporary setting area 12. The wafer W is carried from the temporary setting area 12 to a chuck table 18 by the first carrying means 16 under suction. The wafer W is next held on the chuck table 18 under suction and the annular frame F is fixed to the chuck table 18 by a plurality of clamps 19.

The chuck table 18 is rotatable and reciprocatable in the X direction. Alignment means 20 for detecting the street to be cut on the front side of the wafer W is provided above a path of movement of the chuck table 18 along the X direction. The alignment means 20 includes imaging means 22 for imaging the front side of the wafer W, so that the alignment means 20 can detect the street to be cut by image processing such as pattern matching according to an image obtained by the imaging means 22. The image obtained by the imaging means 22 is displayed by the display means 6.

Provided on the left side of the alignment means 20 as viewed in FIG. 1 is cutting means 24 for performing a cutting operation on the wafer W held on the chuck table 18. The cutting means 24 is integral with the alignment means 20, and they are movable together in the Y direction and the Z direction. The cutting means 24 includes a spindle 26 adapted to be rotationally driven and a cutting blade 28 mounted to the front end of the spindle 26. The cutting means 24 is movable in the Y direction and the Z direction. The cutting blade 28 is located on an extension line extending from the imaging means 22 in the X direction. Reference numeral 25 denotes second carrying means for carrying the wafer W from the chuck table 18 to a cleaning apparatus 27 after performing the cutting operation. The cleaning apparatus 27 functions to clean the wafer W and next dry the wafer W by using a jet of air from an air nozzle.

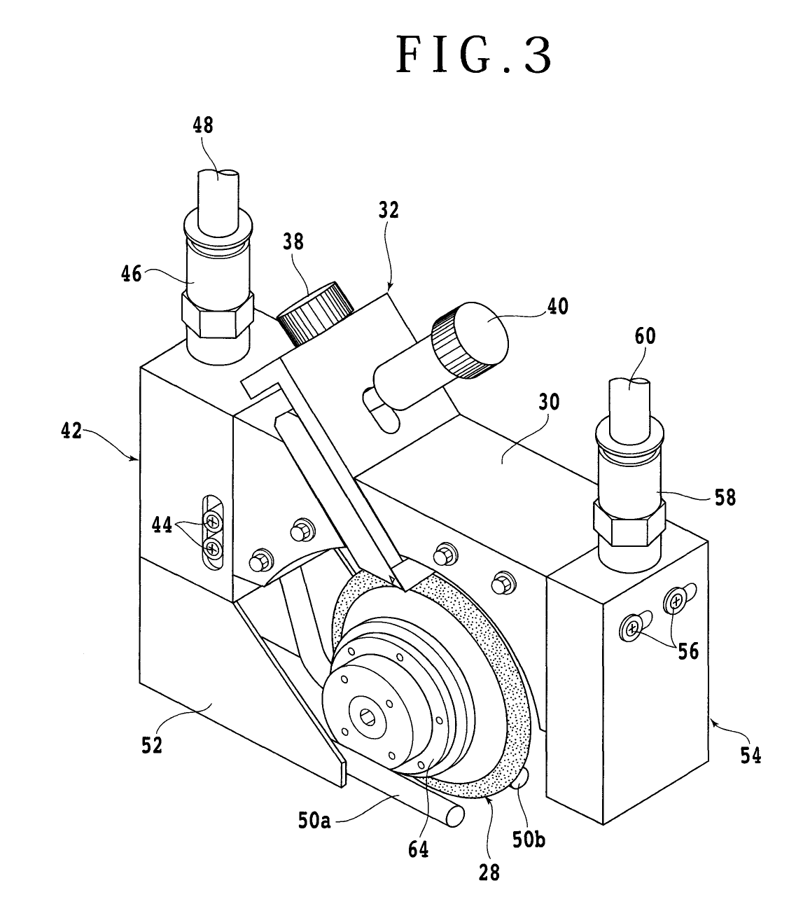

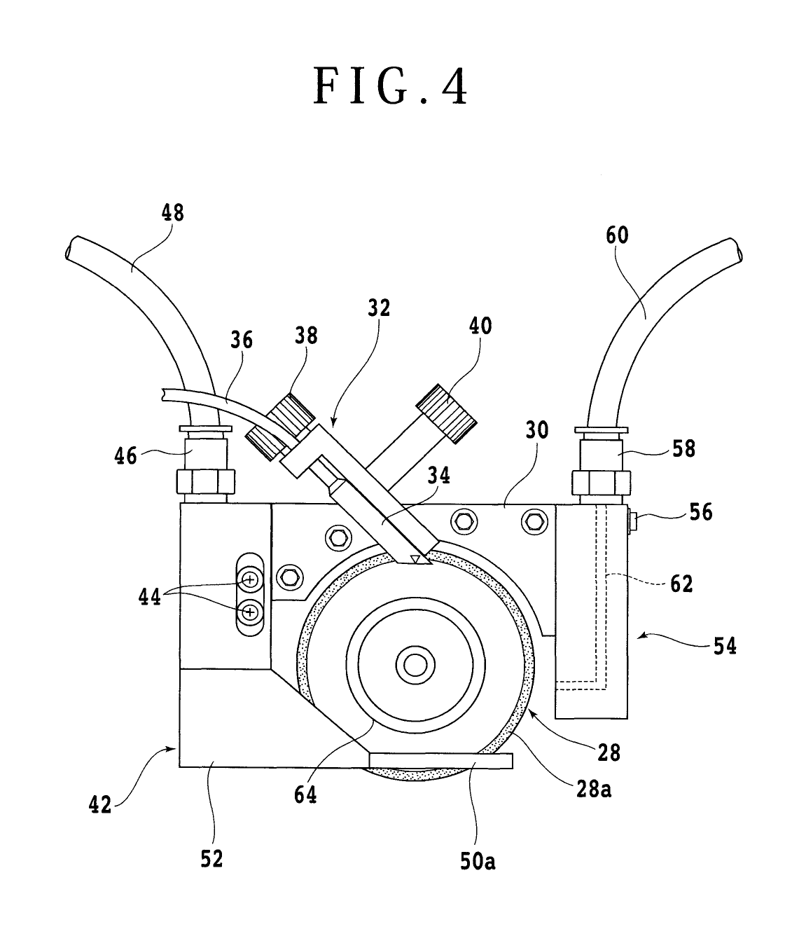

Referring to FIG. 3, there is shown a perspective view of the cutting blade 28 mounted on the spindle 26 in the condition where the cutting blade 28 is surrounded by a wheel cover (blade cover) 30. A blade breakage detector 32 is mounted on the wheel cover 30. As shown in FIG. 4, the blade breakage detector 32 includes a light emitting portion 34 connected to an optical fiber 36 and a photodetecting portion (not shown) connected to an optical fiber (not shown), wherein the front end of the light emitting portion 34 and the front end of the photodetecting portion are opposed to each other so as to interpose a cutting edge 28a of the cutting blade 28. Reference numeral 38 denotes an adjusting screw for adjusting the position of the blade breakage detector 32, and reference numeral 40 denotes a fixing screw for fixing the blade breakage detector 32 at the adjusted position.

An air cylinder (not shown) is provided inside the wheel cover 30, and a mounting plate (not shown) is fixed to the front end of a piston rod in the air cylinder. A cooling water nozzle assembly 42 is fastened to the mounting plate by screws 44. The cooling water nozzle assembly 42 includes a connection pipe 46 connected to a hose 48 and a pair of cooling water nozzles 50a and 50b branched from the connection pipe 46 and extending so as to interpose the cutting blade 28. A splash cover 52 is provided outside of the cooling nozzles 50a and 50b. A cutting water block 54 is fastened to the wheel cover 30 by screws 56. The cutting water block 54 includes a connection pipe 58 connected to a hose 60 and a cutting water nozzle 62 connected to the connection pipe 58. The front end (cutting water outlet) of the cutting water nozzle 62 opens toward the cutting edge 28a of the cutting blade 28.

There will now be described the cutting method of the present invention for cutting the wafer W as a workpiece by using the cutting apparatus 2 mentioned above. The wafer W as a workpiece is held on the chuck table 18 under suction in the condition where the wafer W is supported through the dicing tape T as an adhesive sheet to the annular frame F as shown in FIG. 2. The dicing tape T is composed of a base sheet and an adhesive layer formed on the base sheet. The base sheet is formed of polyvinyl chloride, polyolefin, or PET (polyethylene terephthalate), for example. The adhesive layer is formed of acrylic material or rubber material, for example. The wafer W is attached to the adhesive layer of the dicing tape T.

The wafer W held on the chuck table 18 is moved to a position directly below the imaging means 22 in the X direction, and the wafer W is imaged by the imaging means 22 to perform the alignment operation by the alignment means 20 for detecting the street to be cut. In the condition where the street to be cut and the cutting blade 28 are aligned to each other according to this alignment operation, the cutting blade 28 is rotated at a high speed of about 30,000 rpm and next fed downward in the Z direction to cut into the wafer W. Further, the chuck table 18 is fed in the X direction to thereby cut the street aligned to the cutting blade 28.

In this cutting operation of the present invention, a cutting water cooled to a temperature of 10° C. or less is directed from the cooling water nozzles 50a and 50b toward the cutting blade 28, and a cutting water cooled to a temperature of 10° C. or less is also directed from the cutting water nozzle 62 toward the cutting edge 28a of the cutting blade 28. In the present invention, the cutting water to be directed from the cooling water nozzles 50a and 50b and the cutting water to be directed from the cutting water nozzle 62 must be cooled to a temperature of 10° C. or less, and the lower limit of the temperature of each cutting water is not particularly limited. For example, by mixing an antifreeze into the cutting water, the cutting water can be cooled to minus tens of degrees centigrade without freezing. Preferably, pure water is used as the cutting water.

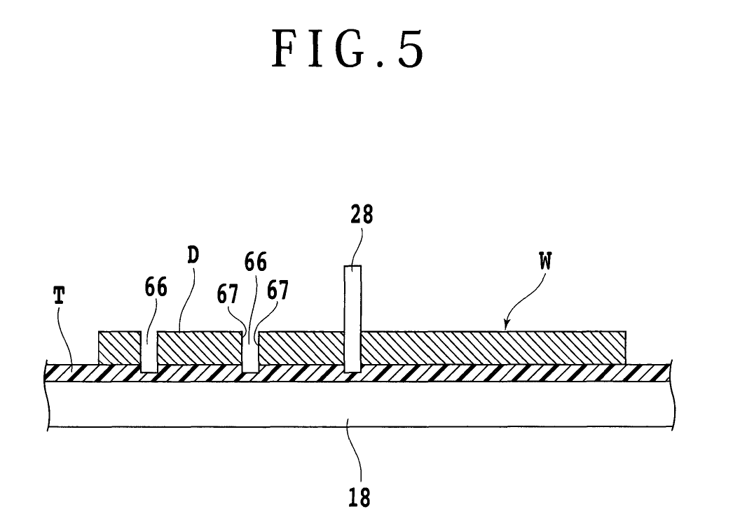

According to the cutting method of the present invention, the cutting water cooled to 10° C. or less is supplied from the cooling water nozzles 50a and 50b and the cutting water nozzle 62 to the cutting blade 28, and the wafer W is cut by the cutting blade 28. Accordingly, the adhesive layer of the dicing tape T is cooled to be hardened by the cutting water led to the outer edge of the cutting blade 28 as a cutting point or by the cutting water scattered on the wafer W. As a result, the adhesive layer of the dicing tape T is prevented from moving during cutting of the wafer W, so that as shown in FIG. 5 the opposed side surfaces 67 of the adjacent devices (chips) D formed as the side walls of each cut groove 66 becomes perpendicular to the dicing tape T. Further, it is possible to suppress the defects such as chipping and cracks on the front or back side of each device D.

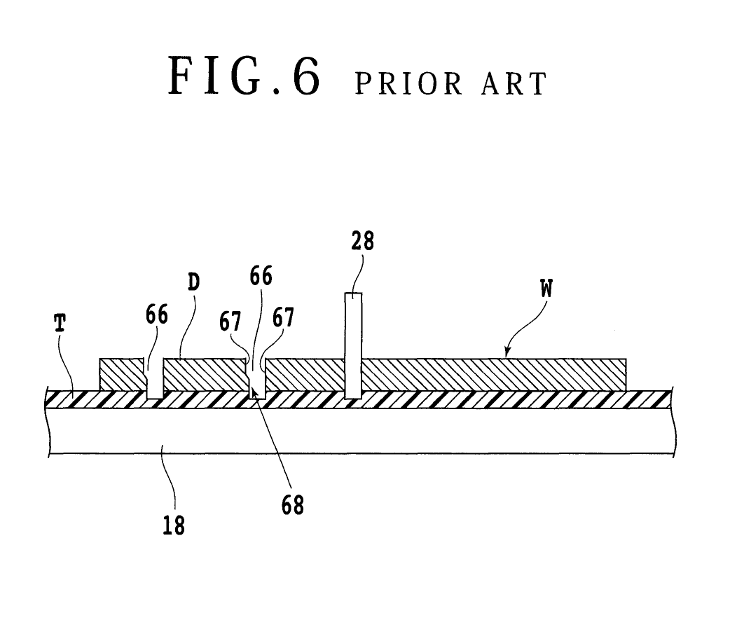

In the conventional method as shown in FIG. 6, a cutting water having a temperature of 21° C. to 22° C. is supplied to the cutting blade 28 during cutting. Since the adhesive layer of the dicing tape T is soft in this conventional method, there is a possibility that an odd form 68 may be formed on any one of the opposed side surfaces 67 of the adjacent devices D exposed to each cut groove 66. Further, there is also a possibility that the defects such as chipping and cracks may be generated on the front or back side of each device D. According to the cutting method of the present invention, the cutting water to be supplied during cutting is cooled to 10° C. or less, thereby solving the above problem to increase the use value.

While the wafer W is used as a workpiece in the above preferred embodiment, the workpiece usable in the present invention is not limited to such a wafer, but any substrate of various materials such as ceramic, sapphire, glass, and resin may be used. Particularly in the case of cutting a hard-to-cut material such as ceramic, quartz glass, and sapphire or in the case of dividing a workpiece into small-sized chips, the rate of generation of an odd form is very high in the conventional method using a cutting water at about 20° C. Accordingly, the cutting method of the present invention is very effective particularly in such cases.

The present invention is not limited to the details of the above described preferred embodiments. The scope of the invention is defined by the appended claims and all changes and modifications as fall within the equivalence of the scope of the claims are therefore to be embraced by the invention.

1. A cutting method for cutting a workpiece by using a cutting blade, said cutting method comprising the steps of:
attaching an adhesive sheet to one surface of said workpiece;
holding said workpiece through said adhesive sheet on holding means; and
feeding said cutting blade into said workpiece until reaching said adhesive sheet while supplying a cutting fluid having a temperature of 10° C. or less to said cutting blade, thereby cutting said workpiece.
